(19) United States
(12) Patent Application Publication
(10) Pub. No.: US 2026/0331417 A1
(43) Pub. Date: Oct. 22, 2026

(54) DETECTION APPARATUS

(71) Applicant: SAMSUNG ELECTRONICS CO., LTD., Suwon-si (KR)

(72) Inventor: Kunihiro FUJITA, Yokohama-shi (JP)

(73) Assignee: SAMSUNG ELECTRONICS CO., LTD., Suwon-si (KR)

(21) Appl. No.: 19/398,930

(22) Filed: Nov. 24, 2025

(30) Foreign Application Priority Data
Apr. 22, 2025 (JP) 2025-070122
Jul. 16, 2025 (KR) 10-2025-0096293

(51) Int. Cl. H01J 37/244; H01J 37/147

(52) U.S. Cl. CPC H01J 37/244; H01J 37/1474; H01J 2237/24485; H01J 2237/24495

(57) ABSTRACT

A detection apparatus includes a charged particle beam generator that generates a first charged particle beam and a second charged particle beam with a delay time therebetween, and a detector that detects reactive charged particles generated from a target irradiated with the first charged particle beam and the second charged particle beam. The first charged particle beam has a first dense structure of charged particles per unit time, and the second charged particle beam has a second dense structure different from the first dense structure per unit time.

### CROSS-REFERENCE TO RELATED APPLICATIONS

This application claims priority from Korean Patent Application No. 10-2025-0096293 filed on Jul. 16, 2025 in the Korean Intellectual Property Office and from Japanese Patent Application No. 2025-070122 filed on Apr. 22, 2025 in the Japan Patent Office, the entire disclosures of each of which being incorporated by reference herein for all purposes.

### BACKGROUND

The present disclosure relates to a detection apparatus using a pump probe method.

Recently, the development of analytical techniques utilizing the pump-probe method has been underway. In the pump-probe method, a target is first excited using a high energy “pump” and changes in the target are measured using an energy “probe”.

### SUMMARY

It is an aspect to provide a detection apparatus and method utilizing charged particle beams for both high-energy pump beams and probe particles.

According to an aspect of one or more example embodiments, there is provided a detection apparatus comprising a charged particle beam generator that generates a first charged particle beam and a second charged particle beam with a delay time therebetween; and a detector that detects reactive charged particles generated from a target irradiated with the first charged particle beam and the second charged particle beam. The first charged particle beam has a first dense structure of charged particles per unit time, and the second charged particle beam has a second dense structure different from the first dense structure per unit time.

According to another aspect of one or more example embodiments, there is provided a detection apparatus comprising a support configured to receive a target; a beam generator that emits a non-pulsed charged particle beam; a pulse generator that deflects the non-pulsed charged particle beam in a first period and that generates a first charged particle beam and an unmodulated second charged particle beam, having a delay time therebetween; a modulator that deflects the unmodulated second charged particle beam in a second period shorter than the first period to generate a second charged particle beam; a scanner that deflects the first charged particle beam and the second charged particle beam and that irradiate the target that is received on the support with the first charged particle beam and the second charged particle beam that have been deflected; and a detector that detects reactive charged particles generated from the target that is irradiated with the first charged particle beam and the second charged particle beam.

According to yet another aspect of one or more example embodiments, there is provided a detection apparatus comprising a support configured to receive a target; a beam generator that generates a pulsed first charged particle beam and an unmodulated second charged particle beam, having a delay time therebetween; a modulator that generates a second charged particle beam by deflecting the unmodulated second charged particle beam with a second period shorter than a first period of the pulsed first charged particle beam; a scanner that deflects the pulsed first charged particle beam and the second charged particle beam and irradiate the target that is received on the support with the pulsed first charged particle beam and the second charged particle beam that have been deflected; and a detector that detects reactive electrons generated from the target that is irradiated with the pulsed first charged particle beam and the second charged particle beam.

According to still another aspect of one or more example embodiments, a detection method includes generating a first charged particle beam and a second charged particle beam having a delay time, and detecting reactive charged particles generated from a target irradiated with the first charged particle beam and the second charged particle beam. The first charged particle beam has a first dense structure of charged particles per unit time, and the second charged particle beam has a second dense structure different from the first dense structure per unit time.

### BRIEF DESCRIPTION OF DRAWINGS

The above and other aspects concept will be more clearly understood from the following detailed description, taken in conjunction with the accompanying drawings, in which:

FIG. 1 is a schematic diagram illustrating an example of a configuration of a detection apparatus according to an example embodiment;

FIG. 2 is a graph illustrating the state of an electron beam at a first position illustrated in FIG. 1, according to an example embodiment;

FIG. 3 is a plan view illustrating an example of a first pass adjustment device illustrated in FIG. 1, according to an example embodiment;

FIG. 4 is a graph illustrating the state of an electron beam at a second position illustrated in FIG. 1, according to an example embodiment;

FIG. 5 is a plan view illustrating an example of a second pass adjustment device illustrated in FIG. 1, according to an example embodiment;

FIG. 6 is a graph illustrating the state of an electron beam at a third position illustrated in FIG. 1, according to an example embodiment;

FIG. 7 is a block diagram illustrating an example of a configuration of an information processing device illustrated in FIG. 1, according to an example embodiment;

FIG. 8 is a block diagram illustrating an example of the functions of a central processing unit (CPU) illustrated in FIG. 7, according to an example embodiment;

FIG. 9A is a graph illustrating a state of a charge signal before a signal processor illustrated in FIG. 8 performs lock-in amplification processing, according to an example embodiment;

FIG. 9B is a graph illustrating a state of the charge signal after the signal processor illustrated in FIG. 8 performs lock-in amplification processing, according to an example embodiment;

FIG. 10 is a flowchart showing an example of a method of detecting reactive electrons performed by the detection apparatus illustrated in FIG. 1, according to an example embodiment;

FIG. 11 is a schematic diagram illustrating an example of a configuration of a detection apparatus according to some example embodiments;

FIG. 12 is a plan view showing an example of a first pass adjustment device and a second pass adjustment device of the detection apparatus illustrated in FIG. 11, according to some example embodiments; and

FIG. 13 is a schematic diagram illustrating an example of a configuration of a detection apparatus according to some example embodiments.

### DETAILED DESCRIPTION

In the pump-probe method, a target may be first excited by irradiating the target with a high-energy pump beam. Subsequent temporal changes in the target may then be measured using probe light or probe particles. For example, in some cases, a laser light may be used as the high-energy pump beam, and electron beams may be used as the probe particles. In some cases, a probe light may be used instead of probe particles.

However, an irradiation spot size of a laser light used for high-energy pump beams is larger than an irradiation spot size of charged particle beams such as electron beams, making an analysis with sufficient precision difficult, in particular for some targets. Therefore, it may be advantageous to use charged particle beams for both the high-energy pump beams and the probe particles.

Hereinafter, embodiments will be described in detail with reference to the attached drawings. In the drawings and description thereof below, identical reference numerals designate identical components, and sizes of respective components in the drawings are expressed at different ratios than in reality for clarity and convenience of explanation. The example embodiments described below are merely illustrative, and various modifications are possible based on these embodiments.

Hereinafter, the terms “upper” or “or” may include not only components directly above in contact but also components above in a non-contact manner.

A component expressed in the singular encompasses plural components unless the context clearly indicates otherwise. Furthermore, when a part is said to “include” or “have” a component, unless otherwise specifically stated, the use of these terms does not exclude other components, but rather implies that other components may be additionally included.

Furthermore, the use of the term “the (above)” and similar descriptive terms applies to both singular and plural meanings.

For the steps of a method, unless explicitly stated in a specific order or otherwise stated to the contrary, the steps are performed in an order and the order in which the steps are described is not necessarily limited to the order that is described. The use of any examples or illustrative terms (e.g., “for example,” “the like,” or “etc.”) is intended solely to illustrate technical concepts and is not intended to limit the scope of the present disclosure as defined by the claims.

### Configuration of Detection Apparatus 1

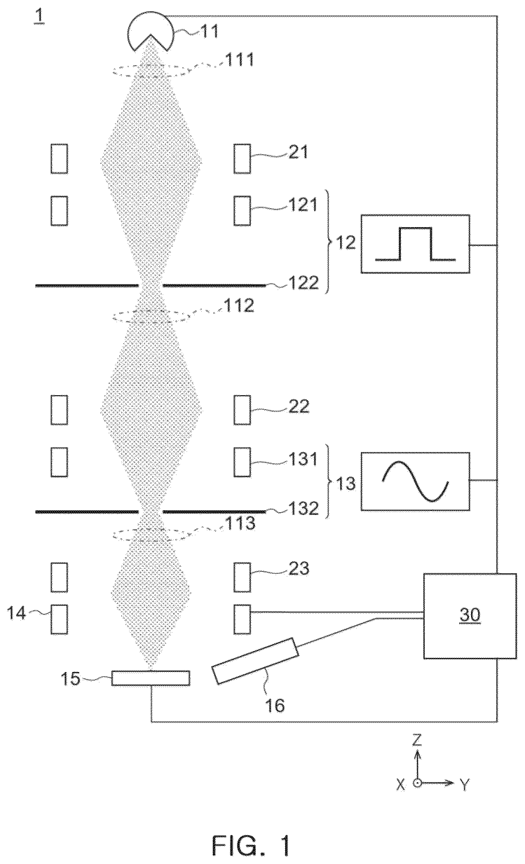

FIG. 1 illustrates an example of a schematic configuration of a detection apparatus 1 according to an example embodiment. The detection apparatus 1 is a detection apparatus utilizing the pump-probe method. The detection apparatus 1 irradiates a target with a high-energy pump beam to excite the target, and then uses probe particles to measure the temporal changes of the target. In detail, the detection apparatus 1 is a time-resolved inspection device. The detection apparatus 1 may generate an image of the target.

The detection apparatus 1 may include, for example, a beam generator 11, a pulse generator 12, a modulator 13, a scanner 14, a support 15, a detector 16, a first optical system 21, a second optical system 22, a third optical system 23, and an information processor 30. The target is disposed on the support 15. The target may be, for example, a semiconductor wafer, or the like. An electron beam generated from the beam generator 11 passes through the first optical system 21, the pulse generator 12, the second optical system 22, the modulator 13, the third optical system 23, and the scanner 14 in this order, and is then irradiated onto the target. In this case, the beam generator 11 and the pulse generator 12 correspond to a detailed example of a charged particle beam generator. In the following description, a direction parallel to a propagation direction of the electron beam may be referred to as a Z-direction, a direction parallel to a deflection direction of the electron beam in the pulse generator 12 and the modulator 13 may be referred to as a Y-direction, and a direction orthogonal to the Z-direction and the Y-direction may be referred to as an X-direction.

The beam generator 11 emits an electron beam, for example, in the Z-direction. The beam generator 11 may include, for example, an electron source and an electron accelerator. The electron source may include, for example, an electron gun and may emit electrons of an energy. The energy may be predetermined. In an electron accelerator, electrons emitted from an electron source are imparted with an amount of kinetic energy. The amount of kinetic energy may be predetermined.

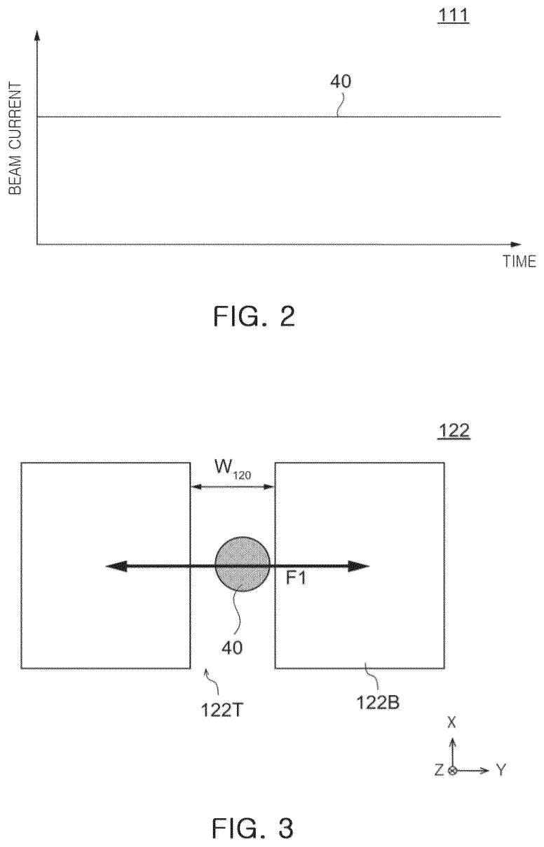

FIG. 2 illustrates an example of a state of an electron beam at a first position 111 in the detection apparatus 1, illustrated in FIG. 1. The first position 111 is a position along an electron beam path between the beam generator 11 and the first optical system 21. For example, the beam generator 11 generates an electron beam with a constant electron density regardless of time. The beam generator 11 may generate, for example, an electron beam that is not pulsed, for example, a non-pulsed electron beam 40.

The first optical system 21 converges the non-pulsed electron beam 40 emitted from the beam generator 11 onto the pulse generator 12 (in more detail, a first pass adjustment device 122 described below). The first optical system 21 may include, for example, a focusing lens.

The pulse generator 12 imparts a first dense structure to the non-pulsed electron beam 40 converged in the first optical system 21. The first dense structure is an electron density pattern per unit time. In detail, the pulse generator 12 periodically changes the number of electrons in the electron beam and imparts the first dense structure to the non-pulsed electron beam 40. The pulse generator 12 includes, for example, a first deflector 121 and a first pass adjustment device 122. The first deflector 121 deflects the non-pulsed electron beam 40 converged in the first optical system 21, in the Y-direction with a first period. The first deflector 121 may include, for example, a pair of electrodes facing each other in the Y-direction. The first pass adjustment device 122 passes a portion of the non-pulsed electron beam 40 deflected by the first deflector 121 therethrough.

FIG. 3 illustrates an example of a configuration of the first pass adjustment device 122, according to an example embodiment. The first pass adjustment device 122 may be configured by, for example, a passage path 122T provided in a plate-shaped member 122B. The main surface of the plate-shaped member 122B is disposed parallel to, for example, the XY plane. The plate-shaped member 122B may be configured by, for example, a metal plate. The metal plate may be conductive. The metal plate may include, for example, stainless steel, titanium, aluminum, or the like.

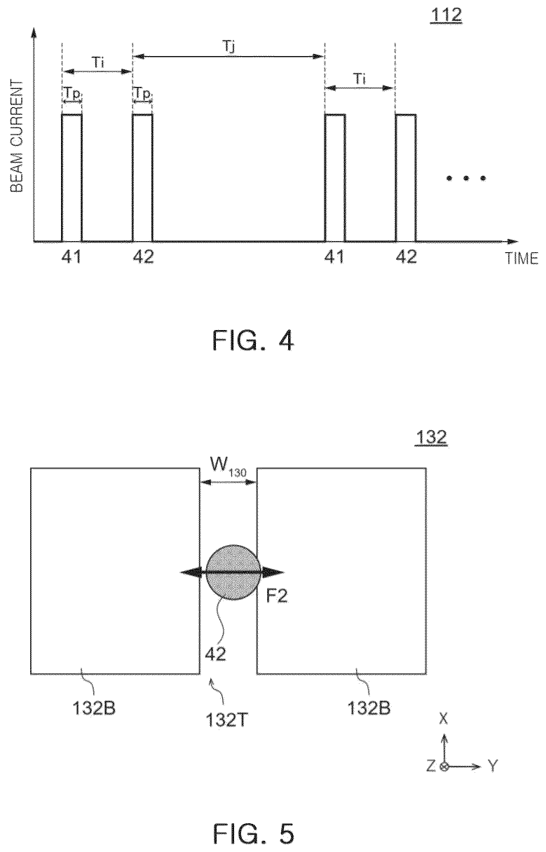

The passage path 122T may be configured by, for example, a slit provided in the plate-shaped member 122B. The slit may extend, for example, in the X-direction. A size W₁₂₀ of the passage path 122T in the Y-direction may be, for example, larger than a spot diameter of the non-pulsed electron beam 40. A fluctuation width F1 of the non-pulsed electron beam 40 deflected in the Y-direction in the first deflector 121 may be larger than the spot diameter of the non-pulsed electron beam 40. The non-pulsed electron beam 40 deflected in the first deflector 121 passes through the passage path 122T while fluctuating with the fluctuation width F1. Accordingly, a pair of a first electron beam 41 and an unmodulated second electron beam 42, having a delay time Ti therebetween are generated (see FIG. 4). The delay time Ti between the first electron beam 41 and the unmodulated second electron beam 42 may be predetermined. The size W₁₂₀ of the passage path 122T in the Y-direction may be the spot diameter of the non-pulsed electron beam 40 or less that the spot diameter.

FIG. 4 illustrates an example of a state of the electron beam at a second position 112 in the detection apparatus 1, illustrated in FIG. 1. The second position 112 is a position on the path of the electron beam between the pulse generator 12 and the second optical system 22. For example, the pulse generator 12 sequentially generates the pair of the pulsed first electron beam 41 and the unmodulated second electron beam 42. The unmodulated second electron beam 42 is generated with a delay time Ti after the first electron beam 41 is generated. After generating the unmodulated second electron beam 42, the pulse generator 12 generates the first electron beam 41 with an interval time Tj after generating the unmodulated second electron beam 42, as illustrated in FIG. 4. The interval time Tj may be, for example, longer than the delay time Ti between the first electron beam 41 and the unmodulated second electron beam 42. In detail, the interval time Tj may be set in consideration of a time until an object excited by irradiation with the first electron beam 41 returns to a de-excited state. The first electron beam 41 and the unmodulated second electron beam 42 both have a first dense structure. The first dense structure, for example, exhibits periodic changes in electron density and may correspond to a rectangular wave pattern with a pulse width Tp. In some example embodiments, the first dense structure may be a triangular wave pattern, a Gaussian distribution pattern, or the like.

The second optical system 22 converges a pair of the first electron beam 41 and unmodulated second electron beam 42, generated by the pulse generator 12, onto the modulator 13 (more specifically onto the second pass adjustment device 132 of the modulator 13 described below). The second optical system 22 may include, for example, a focusing lens.

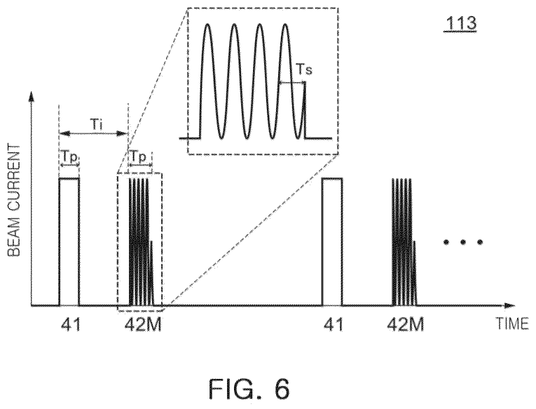

The modulator 13 imparts a second dense structure to the unmodulated second electron beam 42 among a pair of first electron beam 41 and unmodulated second electron beam 42 converged by the second optical system 22. The second dense structure is an electron density pattern per unit time and is different from the first dense structure. In detail, the modulator 13 periodically changes the number of electrons in the unmodulated second electron beam 42 to impart the second dense structure to the unmodulated second electron beam 42. Details will be described later, but in the example embodiment illustrated in FIGS. 1-4, since the detection apparatus 1 includes the modulator 13, reactive electrons generated from the target due to irradiation with the first electron beam 41 and reactive electrons generated from the target due to irradiation with a second electron beam 42M (see FIG. 6 described later) may be distinguished.

The modulator 13 may include, for example, a second deflector 131 and the second pass adjustment device 132. The second deflector 131 deflects the unmodulated second electron beam 42 converged by the second optical system 22 in the Y-direction with a second period that is shorter than the first period of the first deflector 121. The second deflector 131 may include, for example, a pair of electrodes facing each other in the Y-direction. The second pass adjustment device 132 passes a portion of the unmodulated second electron beam 42 deflected by the second deflector 131 therethrough.

FIG. 5 illustrates an example of the configuration of the second pass adjustment device 132. The second pass adjustment device 132 may be configured, for example, by a passage path 132T provided in a plate-shaped member 132B. The main surface of the plate-shaped member 132B is disposed parallel to, for example, the XY plane. The plate-shaped member 132B may include, for example, a metal plate. The metal plate may be conductive. The metal plate may include, for example, stainless steel, titanium, aluminum, or the like. The passage path 132T may include, for example, a slit provided in the plate-shaped member 132B. The slit may extend, for example, in the X-direction. A size W₁₃₀ of the passage path 132T in the Y-direction may be, for example, approximately the same as a spot diameter of the unmodulated second electron beam 42, or may be slightly larger than the spot diameter of the unmodulated second electron beam 42. A fluctuation width F2 of the unmodulated second electron beam 42 deflected in the Y-direction by the second deflector 131 may be approximately the same as the size W₁₃₀ of the passage path 132T in the Y-direction. By adjusting the size W₁₃₀ and fluctuation width F2, electron loss during modulation may be suppressed. In the modulator 13, the unmodulated second electron beam 42 is modulated, and the second electron beam 42M (see FIG. 6) is generated.

FIG. 6 illustrates an example of states of the first electron beam 41 and the second electron beam 42M at a third position 113 of the detection apparatus 1, illustrated in FIG. 1. The third position 113 is a position along the electron beam path between the modulator 13 and the third optical system 23. In the modulator 13, a second dense structure is imparted to the unmodulated second electron beam 42. In detail, the unmodulated second electron beam 42 having the first dense structure is modulated into a second electron beam 42M having the second dense structure. The second dense structure may be, for example, a sinusoidal wave pattern with a period Ts. For example, the period Ts may be shorter than the pulse width Tp of the unmodulated second electron beam 42 (see FIG. 4). The first electron beam 41 passes through the modulator 13 without being modulated. For example, the modulator 13 sequentially generates a pair of the first electron beam 41 and the second electron beam 42, with a delay time Ti therebetween. The second dense structure may correspond to, for example, a sine wave with a period Ts. The second period of the modulator 13 may be expressed by the following equation 1.

Second period=Period Ts/2 [Equation 1]

The third optical system 23 converges a pair of the first electron beam 41 and the second electron beam 42M generated by the modulator 13 onto the scanner 14. The third optical system 23 may include, for example, an objective lens.

The scanner 14 deflects the pair of the first electron beam 41 and the second electron beam 42M converged by the third optical system 23 and irradiates the pair of the first electron beam 41 and the second electron beam 42M onto a target disposed on the support 15. The scanner 14 changes the irradiation positions of the pair of the first electron beam 41 and the second electron beam 42M on the target at a scanning cycle. The scanning cycle may be predetermined. The scanner 14 may include, for example, a pair of electrodes facing each other in the Y-direction. By including the scanner 14 in the detection apparatus 1, mapping becomes possible, enabling the generation of an image representing the state of the target.

The support 15 may include, for example, a mounting platform capable of mounting a target. The mounting surface of the mounting platform is, for example, provided parallel to the XY plane. The mounting surface may also be configured to be movable in the X and Y-directions.

When the target disposed on the support 15 is first irradiated with the first electron beam 41, which functions as a high-energy pump beam, the first electron beam 41 imparts energy to the target, and the object enters an excited state. After irradiation with the first electron beam 41, the target is irradiated with the second electron beam 42M after the delay time Ti. By detecting the reactive electrons generated from the target by the irradiation with the pair of the first electron beam 41 and the second electron beam 42M, status information indicating the state of the target may be generated. The reactive electrons include, for example, secondary electrons and scattered electrons generated from the target.

The detector 16 detects reactive electrons generated from the target resulting from irradiation with the pair of the first electron beam 41 and the second electron beam 42M. The detector 16 further generates a charge signal based on the number of the reactive electrons. The detector 16 may include, for example, an Everhart-Thornley (ET) detector or a semiconductor detector. An ET detector may include, for example, a scintillator, a light guide, and a photomultiplier tube.

The information processor 30 is a computer, such as a personal computer (PC), a smartphone, or a tablet. In some example embodiments, the information processor 30 may include a central processing unit (CPU), a microprocessor, a microcontroller, an application specific integrated circuit (ASIC), or hardware control logic coded to perform various operations. The information processor 30 is connected to the generation device 11, the pulse generator 12, the modulator 13, the scanner 14, the support 15, and the detector 16. In some example embodiment, the hardware control logic may be coded to control the generation device 11, the pulse generator 12, the modulator 13, the scanner 14, the support 15, and the detector 16. In some example embodiment, the computer, the CPU, the ASIC, the microcontroller, or the microprocessor may be configured to control the generation device 11, the pulse generator 12, the modulator 13, the scanner 14, the support 15, and the detector 16 In some example embodiments, the information processor 30 may also be connected to the first optical system 21, the second optical system 22, and the third optical system 23.

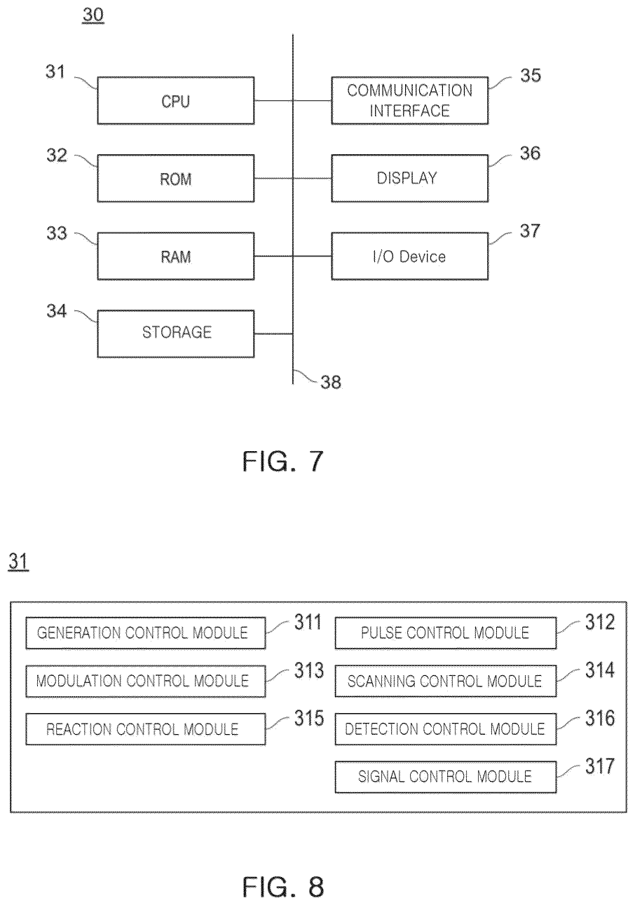

FIG. 7 is a block diagram illustrating the schematic configuration of the information processor 30, according to an example embodiment. The information processor 30 may include, for example, a Central Processing Unit (CPU) 31, a Read Only Memory (ROM) 32, a Random Access Memory (RAM) 33, a storage 34, a communication interface 35, a display 36, and an input/output (I/O) device 37. The CPU 31, the ROM 32, the RAM 33, the storage 34, the communication interface 35, the display 36 and the I/O device 37 are interconnected and communicable via a bus 38.

The CPU 31 controls respective components and performs various computational processing based on programs stored in the ROM 32 and/or storage 34. The detailed functions of the CPU 31 will be described later.

The ROM 32 stores various programs and/or data.

The RAM 33 temporarily stores programs and/or data as a work area.

The storage 34 stores various programs and/or data, including an operating system.

The communication interface 35 is an interface for communicating with other devices. A wired or wireless communication interface conforming to various standards may be used as the communication interface 35.

The display 36 may include a liquid crystal display (LCD) and/or an organic light-emitting display (OLED) and may display various types of information. The display 36 may be configured using viewer software or a printer.

The I/O device 37 may include a touch sensor, a pointing device such as a mouse, a keyboard, or the like and may receive various user operations. In some example embodiments, the display 36 and the I/O device 37 may form a touch panel by superimposing a touch sensor as the I/O device 37 on the display surface of the display 36.

FIG. 8 is a block diagram illustrating the control modules included in the CPU 31. The CPU 31 may operate as a generation control module 311, a pulse control module 312, a modulation control module 313, a scanning control module 314, a reaction control module 315, a detection control module 316, and a signal processing module 317 by executing one or more programs stored in the ROM 32, the RAM 33, the storage 34, or the like. In an example embodiment, the pulse control module 312 may correspond to one detailed example of a controller.

The CPU 31 may execute the generation control module 311 to control the beam generator 11. The CPU 31 may execute the generation control module 311 to control, for example, the energy of the non-pulsed electron beam 40, or the like.

The CPU 31 may execute the pulse control module 312 to control the pulse generator 12. The CPU 31 may execute the pulse control module 312 to control, for example, the delay time Ti, the pulse width Tp, and the interval time Tj. The CPU 31 may execute the pulse control module 312 to generate the pair of the first electron beam 41 and the unmodulated second electron beam 42, for example, by varying the delay time Ti.

The CPU 31 may execute the modulation control module 313 to control the modulator 13. The CPU 31 may execute the modulation control module 313 to control, for example, the period Ts. The CPU 31 may execute the modulation control module 313 to control, for example, the modulator 13 based on a synchronization signal generated by the pulse control module 312.

The CPU 31 may execute the scanning control module 314 to control the scanner 14. The CPU 31 may execute the scanning control module 314 to control, for example, the scanning cycle.

The CPU 31 may execute the reaction control module 315 to control the support 15. For example, The CPU 31 may execute the reaction control module 315 to control a movement of the mounting platform.

The CPU 31 may execute the detection control module 316 to control the detector 16. For example, The CPU 31 may execute the detection control module 316 to control a detection sensitivity and a detection timing of the reactive electrons.

The CPU 31 may execute the signal processing module 317 to generate status information indicating the state of the target based on the charge signal generated by the detector 16. The state of the target may include, for example, a composition of the target, a density of the target, a surface state of the target, and/or physical properties of the target. The CPU 31 may execute the signal processing module 317 to distinguish and process the charge signal derived from the first electron beam 41 and the charge signal derived from the second electron beam 42M. Accordingly, an influence of the high-energy pump beam may be suppressed, and status information based on the charge signal derived from the probe particle may be generated.

The signal processing module 317 may include, for example, a lock-in amplifier. In some embodiments, the CPU 31 may execute the signal processing module 317 to implement the lock-in amplifier. The lock-in amplifier performs lock-in amplification on the charge signal, using, for example, a signal related to the period Ts generated by the modulation control module 313 as a reference signal. In some embodiments, the lock-in amplifier may be implemented in hardware logic as, for example, an amplifier.

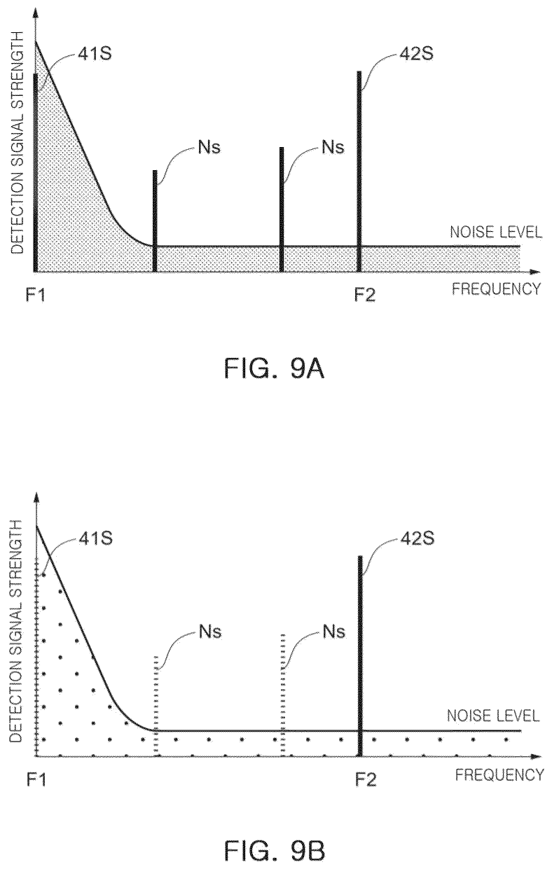

FIGS. 9A and 9B illustrate examples of lock-in amplification, according to an example embodiment. FIG. 9A illustrates a state of a charge signal before lock-in amplification, and FIG. 9B illustrates a state of the charge signal after lock-in amplification. The charge signal before lock-in amplification includes, for example, a charge signal 41s derived from the first electron beam 41, one or more noise signals Ns, and a charge signal 42s derived from the second electron beam 42M. The charge signal 42s contains many components that fluctuate in a sinusoidal manner with a period Ts. The lock-in amplifier may use a sine wave signal with a period Ts as a reference signal and may lock in the charge signal. This configuration and operation allows only the charge signal 42s corresponding to the reference signal to be selectively amplified. Signals not corresponding to the reference signal, for example, the charge signal 41s and the one or more noise signals Ns, may be removed. For example, the signal processing module 317 may generate status information based on the charge signal 42s derived from the second electron beam 42M.

In an example embodiment, the signal processing module 317 may generate status information based on, for example, the charge signal 42s and information regarding the delay time Ti. By generating a plurality of pieces of status information with different delay times Ti, the signal processing module 317 may observe the time response of the target. In detail, time-resolved measurement of the target may be performed.

In an example embodiment, the signal processing module 317 may generate status information based on, for example, the charge signal 42s and information regarding the scanning cycle of the scanner 14. By generating a plurality of pieces of status information at different irradiation locations, the signal processing module 317 may generate an image representing the status of the target. In detail, status information including an image may be generated.

### Detection Method Using Detection Apparatus 1

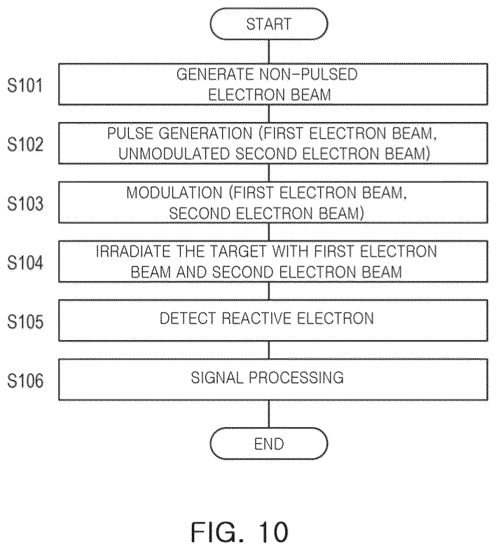

FIG. 10 illustrates an example of a detection method using a detection apparatus 1, according to an example embodiment. The detection apparatus 1 first generates a non-pulsed electron beam 40 (operation S101). For example, the CPU 31 may execute the generation control module 311 to control the beam generator 11, thereby generating the non-pulsed electron beam 40 having an energy. The energy may be predetermined. The generated non-pulsed electron beam 40 is converged, for example, by a first optical system 21.

Next, the detection apparatus 1 performs pulse generation (operation S102). For example, the detection apparatus 1 may pulse the non-pulsed electron beam 40 converged by the first optical system 21. As a result, the pair of the first electron beam 41 and the unmodulated second electron beam 42 are generated. The pair of the first electron beam 41 and the unmodulated second electron beam 42 have a first dense structure. For example, when the CPU 31 executes the pulse control module 312 to control the pulse generator 12, the pair of the first electron beam 41 and the unmodulated second electron beam 42 are generated. The pair of the generated first electron beam 41 and the unmodulated second electron beam 42 are converged, for example, by the second optical system 22.

The detection apparatus 1 performs modulation (operation S103). For example, the detection apparatus 1 modulates the unmodulated second electron beam 42 among the pair of the first electron beam 41 and the unmodulated second electron beam 42 converged by the second optical system 22. In detail, the second dense structure is applied to the unmodulated second electron beam 42, and the second electron beam 42M is generated. For example, the CPU 31 may execute the modulation control module 313 to control the modulator 13, thereby generating the pair of the first electron beam 41 and the second electron beam 42M. The generated pair of the first electron beam 41 and the second electron beam 42M are converged, for example, by the third optical system 23.

The detection apparatus 1 irradiates the target (operation S104). For example, the detection apparatus 1 irradiates the target with the pair of the first electron beam 41 and the second electron beam 42M, converged by the third optical system 23. For example, the CPU 31 may execute the scanning control module 314 to control the scanner 14, thereby irradiating the target of the support 15 with the pair of the first electron beam 41 and the second electron beam 42M.

The detection apparatus 1 detects reactive electrons (operation S105). For example, the detection apparatus 1 detects the reactive electrons generated from the target irradiated with the pair of the first electron beam 41 and the second electron beam 42M. For example, the CPU 31 may execute the detection control module 316 to control the detector 16, thereby detecting the reactive electrons. The detector 16 may generate a charge signal, for example, based on the detected reactive electrons.

The detection apparatus 1 performs signal processing (operation S106). For example, the detection apparatus 1 processes the generated charge signal. In an example embodiment, the detection apparatus 1 may amplify the charge signal derived from the second electron beam 42M, for example, based on the second dense structure provided by the modulator 13. The detection apparatus 1 generates status information based on the amplified charge signal. The detection apparatus 1 detects, for example, reactive electrons generated from the target.

In the detection apparatus 1 according to various example embodiments, the first electron beam 41, which functions as a high-energy pump beam, has a first dense structure, and the second electron beam 42M, which functions as a probe particle, has a second dense structure. Consequently, the reactive electrons generated from irradiation with the second electron beam 42M are detected separately from the reactive electrons generated from irradiation with the first electron beam 41. Therefore, electron beams may be used for both the high-energy pump beam and the probe particle.

As an example of the pump-probe method, a related art technology uses laser light for the high-energy pump beam and electron beams for the probe particle. The irradiation spot size of the laser light used for the high-energy pump beam is often several tens of μm or larger. Furthermore, laser light penetrates the interior of the target more easily than electron beams. Therefore, there is a disadvantage in that it may be difficult to inspect targets with fine patterns using the pump-probe method of the related art technology. For example, in the inspection of micro-processed semiconductor wafers, there is a disadvantage in that it may be difficult to use laser light as the high-energy pump beam.

On the other hand, the irradiation spot size of the electron beam is, for example, in units of nanometers (nm) or less. Furthermore, electron beams have a harder time penetrating the interior of the target than laser light. Therefore, by using electron beams for both the high-energy pump beam and the probe particles, inspection of targets with fine patterns may be performed.

However, using electron beams for both the high-energy pump beam and the probe particles makes it difficult to process the reactive electrons generated from the target during irradiation. In detail, there may be a disadvantage in that it may be difficult to determine whether the reactive electrons generated from the target during electron beam irradiation originate from the high-energy pump beam or the probe particles.

In contrast, in the detection apparatus 1 according to various example embodiments, the electron density structure of the first electron beam 41, which functions as the high-energy pump beam, differs from the electron density structure of the second electron beam 42M, which functions as the probe particles. Accordingly, even when electron beams are used for both the high-energy pump beam and the probe particle beam, the signal charge derived from the probe particle beam may be processed and distinguished from the signal charge derived from the high-energy pump beam. Thus, the detection apparatus 1 using electron beams for both the high-energy pump beam and the probe particle beam may be suitably used for the inspection of, for example, semiconductor wafers with fine patterns, and the like.

According to various example embodiments, the detection apparatus 1 enables measurement of the temporal response of a target at a shorter period than when laser light is used for the high-energy pump beam. The detection apparatus 1 enables measurement of temporal responses in the picosecond to subpicosecond range, for example.

Furthermore, when observing a target such as a semiconductor wafer using an electron microscope, electron irradiation during the observation may cause charge-up and carrier generation in the target, which may affect the observation. The detection apparatus 1 according to various example embodiments that uses electron beams for both the high-energy pump beam and the probe particles may acquire information under conditions identical to conditions observed with an electron microscope, contributing to the understanding of phenomena such as charge-up and carrier generation.

The detection apparatus 1 according to various example embodiments eliminates the need for a device (e.g., a laser source) for generating laser light, enabling miniaturization.

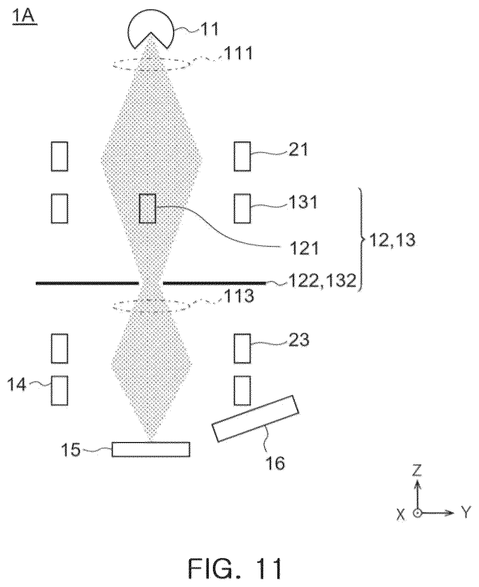

FIG. 11 illustrates an example of a configuration of a detection apparatus according to an example embodiment. In the following description, detailed descriptions of components identical to components of the detection apparatus 1 described above will be omitted for conciseness. In a detection apparatus 1A, the pulse generator 12 and the modulator 13 are disposed at approximately a same location in the electron path. Aside from this configuration, the detection apparatus 1A has the same configuration as the detection apparatus 1 described above with respect to FIGS. 1-10. Approximately the same position includes a state in which the pulse generator 12 and the modulator 13 are disposed to exhibit the following operational effects, and for example, misalignment due to a thickness of the plate-shaped member, misalignment due to placement errors, or the like is permitted.

The first deflector 121 includes, for example, a pair of electrodes facing each other in the X-direction, and the second deflector 131 includes, for example, a pair of electrodes facing each other in the Y-direction.

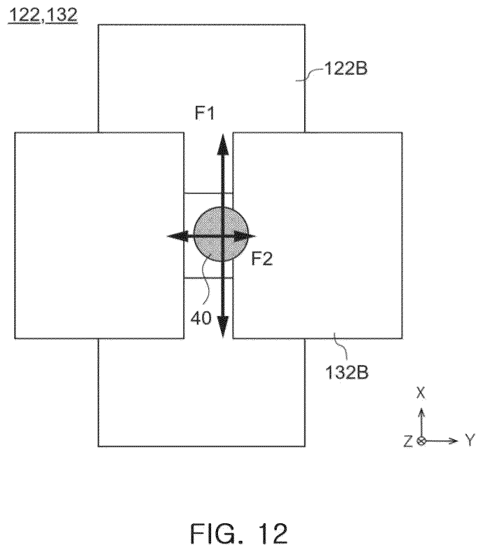

FIG. 12 illustrates an example of a configuration of a first-pass adjustment device 122 and a second-pass adjustment device 132. The plate-shaped member 122B constituting the first-pass adjustment device 122 and the plate-shaped member 132B constituting the second-pass adjustment device 132 are disposed, for example, overlapping in the Z-direction. A slit (passage path 122T) provided in the plate-shaped member 122B extends, for example, in the Y-direction. A slit (passage path 132T) provided in the plate-shaped member 132B extends, for example, in the X-direction.

In the detection apparatus 1A according to an example embodiment, similar to the detection apparatus 1, the first electron beam 41 functioning as a high-energy pump beam has a first dense structure, and the second electron beam 42M functioning as a probe particle has a second dense structure. Accordingly, the reactive electrons generated from irradiation with the second electron beam 42M may be detected separately from the reactive electrons generated from irradiation with the first electron beam 41.

Furthermore, since the pulse generator 12 and modulator 13 are disposed at the same location in the electron path, the electron path from the beam generator 11 to the support 15 is shortened, thereby contributing to device miniaturization.

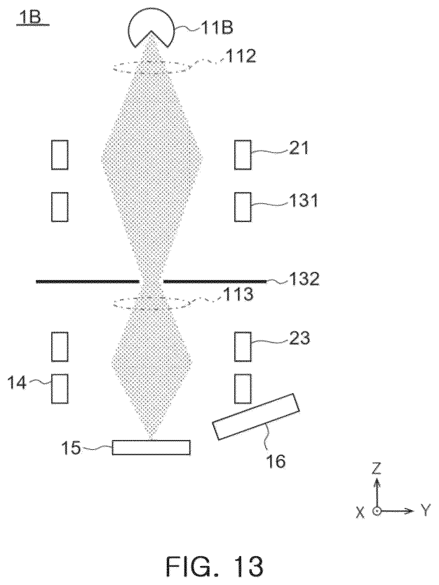

FIG. 13 illustrates an example of a configuration of a detection apparatus according to an example embodiment. In the following description, detailed descriptions of components identical to components of the detection apparatus 1 described above will be omitted for conciseness. A detection apparatus 1B has a beam generator 11B instead of the beam generator 11 described in above with respect to FIGS. 1-10, and the beam generator 11B generates a pair of a pulsed first electron beam and the unmodulated second electron beam 42. Except for this point, the detection apparatus 1B has the same configuration as the detection apparatus 1 described above.

The beam generator 11B may include, for example, a photocathode-type electron gun. The beam generator 11B generates the pair of the pulse first electron beam and the unmodulated second electron beam 42, having the delay time Ti, by irradiating pulsed laser light.

In the detection apparatus 1B according to an example embodiment, similar to the detection apparatus 1, the pulsed first electron beam, which functions as a high-energy pump beam, has a first dense structure, and the second electron beam 42M, which functions as a probe particle, has a second dense structure. Consequently, the reactive electrons generated from irradiation with the second electron beam 42M may be detected separately from the reactive electrons generated from irradiation with the first electron beam 41.

Furthermore, since the beam generator 11B generates the pair of the pulsed first electron beam and the unmodulated second electron beam 42, the pulse generator (the pulse generator 12 in FIG. 1) becomes unnecessary. Therefore, the device may be miniaturized.

The configurations of the detection apparatuses 1, 1A and 1B described above are merely a description of the main components in explaining the features of the above-described embodiments. The configuration is not limited to the above-described configuration and may be modified in various ways within the scope of the claims. Furthermore, the example embodiments do not exclude configurations typically found in detection apparatuses.

For example, the detection apparatus 1, 1A, 1B may include a plurality of the detectors 16.

In the above example embodiments, the detection apparatuses 1, 1A and 1B are described as examples in which the first electron beam 41 and the second electron beam 42M are irradiated onto the target, but the detection apparatuses 1, 1A and 1B according to example embodiments may also irradiate the first ion beam as a high-energy beam for the pump and the second ion beam as a particle for the probe, onto the target. In this case, the first ion beam may have a first dense structure of ions per unit time, and the second ion beam may have a second dense structure per unit time, which is different from the first dense structure. In some example embodiments, the detection apparatus 1, 1A, 1B may irradiate the first ion beam as a high-energy beam for the pump and the second electron beam as a particle for the probe, onto the target, or may irradiate the first electron beam as a high-energy beam for the pump and the second ion beam as a particle for the probe, onto the target.

While the above example embodiments described examples in which the passage paths 122T and 132T have a slit shape, the passage paths 122T and 132T may have other shapes. The passage paths 122T and 132T may be formed by openings, such as circles, ellipses, or polygons, provided in the plate-shaped members 122B and 132B.

In some example embodiments, the beam generator of the detection apparatus may generate the pair of the first electron beam 41 and the second electron beam 42M. In this case, the pulse generator and modulator (pulse generator 12 and modulator 13 in FIG. 1) become unnecessary.

While FIGS. 3 and 5, and the like, describe examples in which the electron beams are deflected in the Y-direction, the electron beams may also be deflected in the X-direction.

As set forth above, in a detection apparatus according to various example embodiments, a first charged particle beam functioning as a high-energy beam for a pump has a first dense structure, and a second charged particle beam functioning as a probe particle has a second dense structure different from the first dense structure. Accordingly, reactive charged particles derived from irradiation of the second charged particle beam may be detected by distinguishing the reactive charged particles derived from irradiation of the second charged particle beam from reactive charged particles derived from the first charged particle beam. Therefore, a charged particle beam may be used for both the high-energy beam for a pump and the particles for a probe.

While various example embodiments have been illustrated and described above with reference to the drawings, it will be apparent to those skilled in the art that modifications and variations could be made without departing from the scope of the present disclosure as defined by the appended claims.

What is claimed is:

1. A detection apparatus comprising:
a charged particle beam generator that generates a first charged particle beam and a second charged particle beam with a delay time therebetween; and
a detector that detects reactive charged particles generated from a target irradiated with the first charged particle beam and the second charged particle beam,
wherein the first charged particle beam has a first dense structure of charged particles per unit time, and the second charged particle beam has a second dense structure different from the first dense structure per unit time.

2. The detection apparatus of claim 1, wherein the charged particle beam generator includes,
a beam generator that generates a non-pulsed charged particle beam;
a pulse generator that imparts the first dense structure to the non-pulsed charged particle beam, and that generates the first charged particle beam and an unmodulated second charged particle beam, having the delay time therebetween; and
a modulator that imparts the second dense structure to the unmodulated second charged particle beam among the first charged particle beam and the unmodulated second charged particle beam, and generates the second charged particle beam.

3. The detection apparatus of claim 2, wherein the pulse generator includes:
a first deflector that deflects the non-pulsed charged particle beam with a first period to generate a deflected non-pulsed charged particle beam; and
a first pass adjustment device that passes a portion of the deflected non-pulsed charged particle beam therethrough, and that generates the first charged particle beam and the unmodulated second charged particle beam.

4. The detection apparatus of claim 3, wherein the modulator includes:
a second deflector that deflects the unmodulated second charged particle beam at a second period different from the first period to generate a deflected unmodulated second charged particle beam; and
a second pass adjustment device that passes a portion of the deflected unmodulated second charged particle beam therethrough and that generates the second charged particle beam.

5. The detection apparatus of claim 2, wherein the pulse generator and the modulator are disposed at approximately a same position along a path from the charged particle beam generator to the detector.

6. The detection apparatus of claim 1, wherein the detector generates a charge signal based on the reactive charged particles.

7. The detection apparatus of claim 6, further comprising a central processing unit that executes a signal processing module to generate status information indicating a state of the target based on the charge signal.

8. The detection apparatus of claim 7, wherein the signal processing module includes a lock-in amplifier,
wherein the central processing unit executes the signal processing module to perform lock-in amplification processing on the charge signal using the lock-in amplifier, based on the second dense structure.

9. The detection apparatus of claim 7, further comprising a scanner that changes irradiation positions of the first charged particle beam and the second charged particle beam on the target at a scanning cycle,
wherein the status information includes an image representing a status of the target using a plurality of pieces of status information at different irradiation positions.

10. The detection apparatus of claim 7, further comprising a controller that controls the delay time,
wherein the central processing unit executes the signal processing module to generate a plurality of pieces of status information having different delay times.

11. The detection apparatus of claim 1, wherein the first charged particle beam and the second charged particle beam are electron beams.

12. The detection apparatus of claim 1, wherein the first charged particle beam and the second charged particle beam are ion beams.

13. The detection apparatus of claim 1, wherein the first charged particle beam is an electron beam, and the second charged particle beam is an ion beam, or
the first charged particle beam is an ion beam, and the second charged particle beam is an electron beam.

14. The detection apparatus of claim 4, wherein the second period is shorter than the first period.

15. A detection apparatus comprising:
a support configured to receive a target;
a beam generator that emits a non-pulsed charged particle beam;
a pulse generator that deflects the non-pulsed charged particle beam in a first period and that generates a first charged particle beam and an unmodulated second charged particle beam, having a delay time therebetween;
a modulator that deflects the unmodulated second charged particle beam in a second period shorter than the first period to generate a second charged particle beam;
a scanner that deflects the first charged particle beam and the second charged particle beam and that irradiate the target that is received on the support with the first charged particle beam and the second charged particle beam that have been deflected; and
a detector that detects reactive charged particles generated from the target that is irradiated with the first charged particle beam and the second charged particle beam.

16. The detection apparatus of claim 15, wherein the detector generates a charge signal based on the reactive charged particles,
wherein the detection apparatus further includes an information processor that is configured to selectively amplify the charge signal corresponding to the second period by lock-in amplification of the charge signal.

17. The detection apparatus of claim 16, wherein the scanner changes irradiation positions of the first charged particle beam and the second charged particle beam on the target at a scanning cycle, and
the information processor is configured to generate an image representing a status of the target based on a plurality of pieces of status information with different irradiation positions.

18. The detection apparatus of claim 16, wherein the information processor is configured to control the delay time and to generate a plurality of pieces of status information with different delay times to perform time-resolved measurement of the target.

19. The detection apparatus of claim 15, wherein:
the first charged particle beam has a rectangular wave pattern, a triangular wave pattern, or a Gaussian distribution pattern with a pulse width, and
the second charged particle beam has a sinusoidal wave pattern.

20. A detection apparatus comprising:
a support configured to receive a target;
a beam generator that generates a pulsed first charged particle beam and an unmodulated second charged particle beam, having a delay time therebetween;
a modulator that generates a second charged particle beam by deflecting the unmodulated second charged particle beam with a second period shorter than a first period of the pulsed first charged particle beam;
a scanner that deflects the pulsed first charged particle beam and the second charged particle beam and irradiate the target that is received on the support with the pulsed first charged particle beam and the second charged particle beam that have been deflected; and
a detector that detects reactive electrons generated from the target that is irradiated with the pulsed first charged particle beam and the second charged particle beam.
